(19) United States
(12) Patent Application Publication
(10) Pub. No.: US 2014/0354287 A1
(43) Pub. Date: Dec. 4, 2014

(54) APPARATUS FOR TESTING AN ELECTROMECHANICAL RELAY

(71) Applicant: Solar Turbines Incorporated, San Diego, CA (US)

(72) Inventor: Ifegwu Eziyi, Tallahassee, FL (US)

(73) Assignee: Solar Turbines Incorporated, San Diego, CA (US)

(21) Appl. No.: 14/459,658

(22) Filed: Aug. 14, 2014

(51) Int. Cl. G01R 31/327; G01R 1/30

(52) U.S. Cl. CPC G01R 31/3278; G01R 1/30
USPC 324/418

(57) ABSTRACT

A portable apparatus for testing an electromechanical relay having Normally Closed (NC) contacts, Normally Open (NO) contacts, and an electromagnetic coil therein includes a housing, a battery, a battery test circuit, and a relay test circuit. The battery test circuit includes a first switch operable to provide a first type of indication based on a voltage output by the battery. The relay test circuit includes a second switch, and a third switch. The second switch is operable to provide a second type of indication if an electrical circuit of the relay test circuit is complete with the NC contacts of the relay. The third switch is operable to energize the electromagnetic coil and provide the second type of indication if NO contacts of the relay become closed upon energizing the electromagnetic coil, thus opening the NC contacts of the relay.

### TECHNICAL FIELD

The present disclosure generally relates to an apparatus for testing an electromechanical relay. More particularly, the present disclosure relates to a portable battery-operated apparatus for testing an electromechanical relay.

### BACKGROUND

Typically, relays have been used to accomplish control of various types of electronic and/or electrical devices. With an ever increasing use of relays in present day devices, it may be required to test the relays to determine a functioning of the relays. As such, these tests may detect or identify any faulty and/or non-operative relays and thereafter, facilitate a technician to accomplish quick and easy replacement of the relays.

Various systems have been developed in the past to perform testing of relays. U.S Publication No. 2004/0085071 relates to an apparatus for testing an electrical relay. The apparatus comprises a portable housing and an electrical testing circuit within the housing for performing various types of tests on the relay. However, such previously known systems may not be provided with self diagnostic and/or testing functions to ensure a proper functioning of the system itself before being used for testing of the relays.

### SUMMARY OF THE DISCLOSURE

In one aspect of the present disclosure, a portable apparatus for testing an electromechanical relay having Normally Closed (NC) contacts, Normally Open (NO) contacts, and an electromagnetic coil is provided. The apparatus includes a housing, a battery disposed within the housing, a battery test circuit, and a relay test circuit. The battery has a first terminal and a second terminal disposed in selective communication with a battery test circuit and a relay test circuit, the battery test circuit and the relay test circuit being parallelly arranged to one another.

The battery test circuit includes a first switch operable to provide a first type of indication based on a voltage output by the battery. The relay test circuit includes a second switch, and a third switch. The second switch is operable to provide a second type of indication if an electrical circuit of the relay test circuit is complete with the NC contacts of the relay. The third switch is operable to energize the electromagnetic coil and provide the second type of indication if the NO contacts of the relay become closed upon energizing the electromagnetic coil, thus causing the NC contacts of the relay to become open.

In another aspect of the present disclosure, a portable apparatus for testing an electromechanical relay having Normally Closed (NC) contacts, Normally Open (NO) contacts, and an electromagnetic coil therein is provided. The apparatus includes a battery, a battery test circuit, and a relay test circuit.

The battery has a first terminal and a second terminal. The battery test circuit is communicably connected to the battery. The battery test circuit includes a first resistance element, a first visual indication device, and a first switch. The first resistance element is connected in series and disposed downstream of the first terminal. The first visual indication device is connected in parallel to the first resistance element. The first switch is disposed between the first visual indicator device and the second terminal of the battery. The first switch is operable to allow illumination of the first visual indication device based on a voltage output by the battery.

The relay test circuit is communicably coupled to the battery and disposed parallel to the battery test circuit. The relay test circuit is configured to allow connection with the electromagnetic coil, the NC contacts, and the NO contacts of the relay. The relay test circuit includes a second visual indication device, a second resistance element, a second switch, and a third switch.

The second visual indication device is connected in series and disposed downstream of the NC and NO contacts of the relay. The second resistance element is connected in series with the second visual indication device and disposed between the second visual indication device and the second terminal of the battery. The second switch is connected in series with the NC contacts of the relay. The second switch is operable to allow illumination of the second visual indication device if an electrical circuit of the relay test circuit is complete with the NC contacts of the relay.

The third switch is disposed between the second resistance element and the second terminal of the battery. The third switch is operable to energize the electromagnetic coil and provide the second type of indication if the NO contacts of the relay become closed upon energizing the electromagnetic coil, causing the NC contacts of the relay to become open.

Other features and aspects of this disclosure will be apparent from the following description and the accompanying drawings.

### BRIEF DESCRIPTION OF THE DRAWINGS

FIG. 1 is a front perspective view of an apparatus in accordance with an embodiment of the present disclosure, the apparatus being shown in conjunction with an illustrative electromechanical relay;

FIG. 2 is a schematic representation of a battery test circuit and a relay test circuit employed by the apparatus;

FIG. 3 is a front view of the apparatus shown in a state of operation associated with a first switch of the battery test circuit; and

FIG. 4 is a schematic representation of the apparatus in accordance with the state of operation described in FIG. 3;

FIG. 5 is a front view of the apparatus shown in a state of operation associated with a second switch of the battery test circuit;

FIG. 6 is schematic representation of the apparatus in accordance with the state of operation described in FIG. 5;

FIG. 7 is a front view of the apparatus shown in a state of operation associated with a third switch of the battery test circuit; and

FIG. 8 is schematic representation of the apparatus in accordance with the state of operation described in FIG. 7.

### DETAILED DESCRIPTION

Wherever possible, the same reference numbers will be used throughout the drawings to refer to same or like parts. Moreover, references to various elements described herein are made collectively or individually when there may be more than one element of the same type. However, such references are merely exemplary in nature. It may be noted that any reference to elements in the singular is also to be construed to relate to the plural and vice-versa without limiting the scope of the disclosure to the exact number or type of such elements unless set forth explicitly in the appended claims.

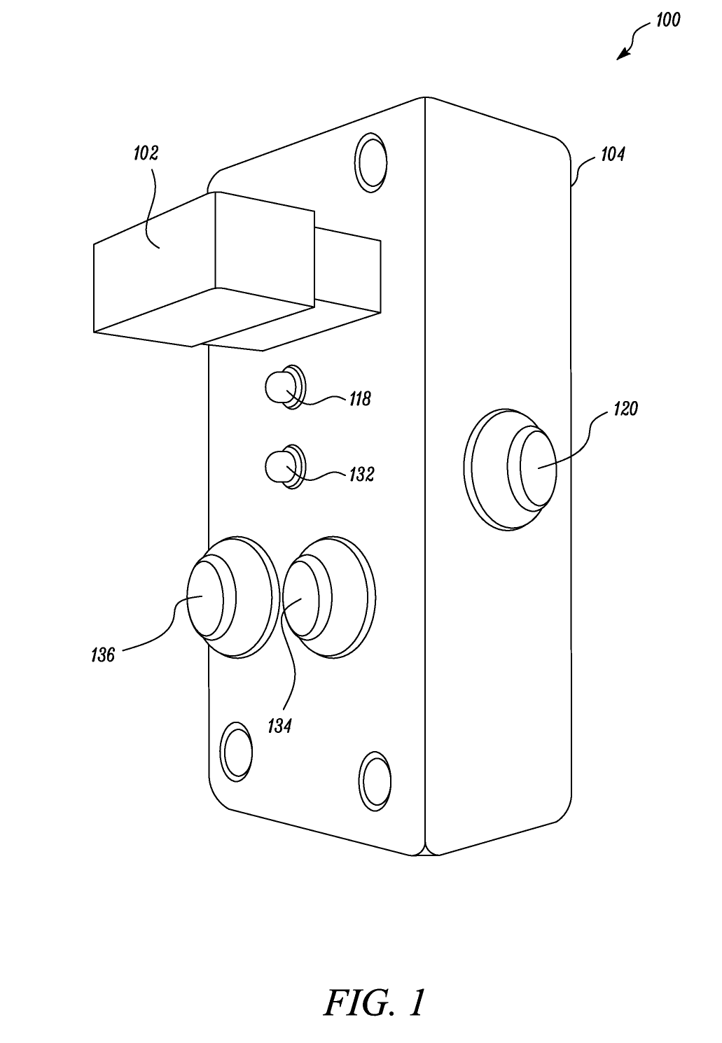

FIG. 1 shows front perspective view of an apparatus 100 in accordance with an embodiment of the present disclosure. As shown, the apparatus 100 is used to test an electromechanical relay 102. The relay 102 being tested may be an 8 pin Double Pole Double Throw relay (DPDT) such as, for e.g., a Shrack® relay model no: RT940005.

Although the present disclosure is explained in conjunction with an 8 pin DPDT, relays with fewer or more pins are readily known, and one skilled in the art could adapt the structures and the methods disclosed herein for testing such relays. Therefore, it must be noted that the 8 pin DPDT disclosed herein is non-limiting of this disclosure and hence, in alternative embodiments, the apparatus 100 could be suitably configured for testing relays with other number and/or configurations of pins in place of the 8 pin DPDT disclosed herein. For example, the apparatus 100 may be used to test a 5 pin single pole single throw (SPST) relay, 14 pin DPDT, or an 11 pin DPDT.

Referring to FIG. 1, the apparatus 100 includes a housing 104 that is configured to fit within the palm of a user. As such, in an aspect of the present disclosure, it is contemplated that the housing 104 is beneficially sized and/or shaped so as to facilitate ease of handling while also being easily portable from one location to another. Moreover, the housing 104 may be formed from an electrically non-conductive material such as, but not limited to, plastic.

The housing 104 may be configured to accommodate and/or enclose the components of the apparatus 100 disclosed herein. The various components of the apparatus 100 may be fully enclosed or partially enclosed within the housing 104 depending on the intended function/s of the respective components. Explanation to component and/or system hardware illustrated in FIG. 1 will be made later herein.

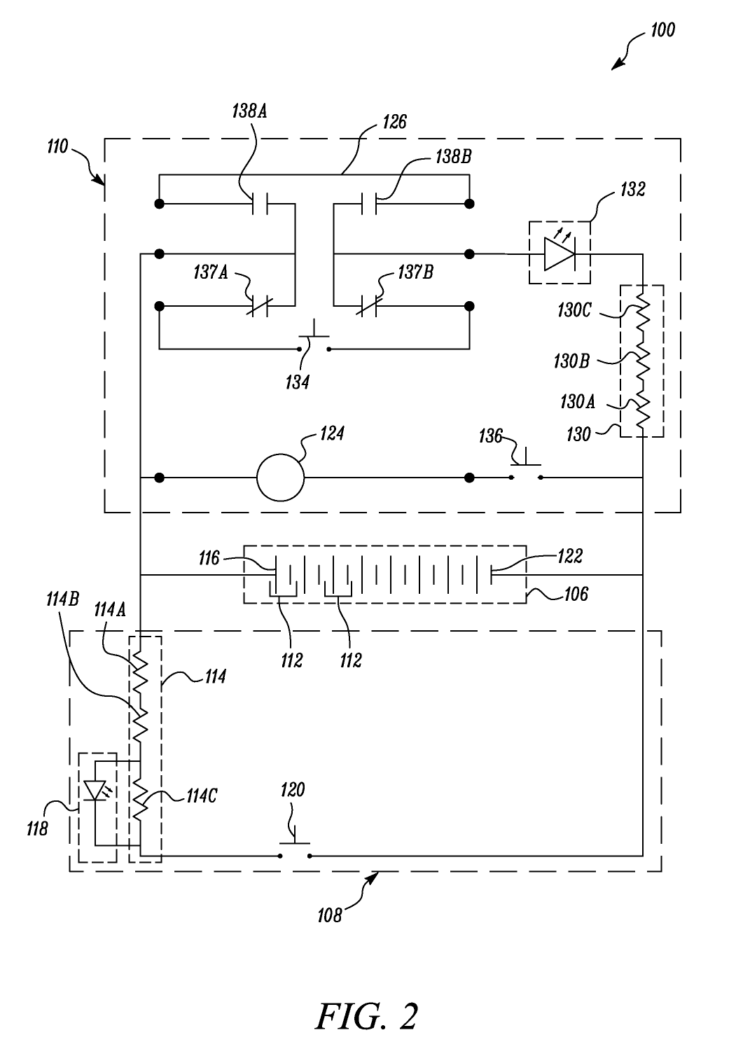

The apparatus 100 includes a battery 106, a battery test circuit 108, and a relay test circuit 110 that are schematically illustrated in FIG. 2. The battery 106 may include a plurality of 3 volt button cell Lithium batteries 112 that are connected in series. In the exemplary embodiment of FIG. 2, eight 3 volt (V) cells 112 are shown disposed in series and may be regarded as forming a 24V battery. However, it will be appreciated that other number of cells and/or types of battery such as but not limited to, Nickel-Cadmium (Ni-Cad) batteries, Zinc-Air cells and the like may be used in lieu of the button cell Lithium battery. Moreover, it will be further appreciated that the batteries could be of a rechargeable type or a disposable type.

As further shown in FIG. 2, the battery test circuit 108 and the relay test circuit 110 are communicably connected to the battery 106. Moreover, the relay test circuit 110 is disposed parallel to the battery test circuit 108. The battery test circuit 108 includes a first resistance element 114, a first visual indication device 118, and a first switch 120. As shown, the first resistance element 114 is connected in series and disposed downstream of the first terminal 116. Optionally, as shown in the illustrated embodiment of FIG. 2, the first resistance element 114 includes multiple resistance elements 114a, 114b, and 114c therein. Each of the resistance elements 114a, 114b, and 114c is rated at resistance values of 1 kilo-Ohm (kΩ), 1 kilo-Ohm (kΩ), and 330 Ohms (Ω), respectively. However, the first resistance element 114 may be implemented by other number of resistance elements having similar or dissimilar resistance values depending on specific requirements of an application.

The first visual indication device 118 is connected in parallel to the first resistance element 114. In the illustrated embodiments of FIGS. 1 and 2, the first visual indication device 118 is embodied in the form of a light emitting diode (LED).

The first switch 120 is disposed between the first visual indicator device and a second terminal 122 of the battery 106. In the structural representation of FIG. 1, the first switch 120 is physically embodied in the form of a push-button switch and designated by the same numeral ‘120’.

Referring to FIG. 2, the first switch 120 is operable to allow illumination of the first visual indication device 118 based on a voltage output by the battery 106. In an embodiment, the first switch 120 may be operable to allow illumination of the first visual indication device 118 based on a minimum output voltage of 18 volts from the battery 106.

It may be noted that the apparatus 100 of the present disclosure may additionally include associated system hardware such as controllers, comparators, multiplexers and other electrical components to facilitate a comparison between the voltage output by the battery 106 and a threshold value set in the associated system hardware. Such system hardware may be beneficially regarded as forming part of the battery test circuit 108 disclosed herein. As such, various hardware components are known to one of ordinary skill in the art and such components may be readily implemented to determine an illumination of the first visual indication device 118 on the basis of the comparison between the voltage output by the battery 106 and the threshold value set at the associated system hardware.

Additionally, in alternative embodiments of the present disclosure, it can also be contemplated to change the threshold value of the minimum output voltage at which the first visual indication device 118 may provide the indication of the battery 106 being sufficiently charged to carry out testing procedures consistent with the present disclosure. For example, in another application, the first visual indication device 118 may be configured to illuminate if a minimum of 20 volts or 22 volts is output from the battery 106.

As disclosed earlier herein, the relay test circuit 110 is disposed parallel to the battery test circuit 108. The relay test circuit 110 is configured to allow connection with the relay 102. The apparatus 100 also includes a socket 128 that is configured to allow a connection of the relay 102 that is to be tested (See FIGS. 1, 5, and 7). In an embodiment, the socket may be an Integrated Circuit (IC) based socket.

With reference to embodiments disclosed herein, the socket 128 is configured to allow connection with the 8 pin Double Pole Double Throw (DPDT) relay 102. However, it may be noted that the type and/or configuration of the socket 128 can be varied to suit and facilitate connection with other configurations of relays known to one skilled in the art.

The relay test circuit 110 includes a second visual indication device 132, a second resistance element 130, a second switch 134, and a third switch 136. Referring to FIG. 2, the second visual indication device 132 is connected in series and disposed downstream of the NC and NO contacts 137A, 137B and 138A, 138B of the relay 102. In the illustrated embodiments of FIGS. 1 and 2, the second visual indication device 132 may be structurally embodied in the form of a light emitting diode (LED).

The second resistance element 130 is connected in series with the second visual indication device 132 and disposed between the second visual indication device 132 and the second terminal 122 of the battery 106. Moreover, in the illustrated embodiment, the second resistance element 130 may include multiple resistance elements 130a, 130b, and 130c; each having the respective values of 1 kilo-Ohm (kΩ), 1 kilo-Ohm (kΩ) and 300 Ohms (Ω) and which can be arranged in any order in series. However, the second resistance element 130 may be implemented by other number of resistance elements having similar or dissimilar resistance values depending on specific requirements of an application.

The second switch 134 is disposed between the NC contacts 137A, 137B of the relay; while the third switch 136 is disposed between the second resistance element 130 and the second terminal 122 of the battery 106. In the structural representation of FIG. 1, the second and third switches 134, 136 are physically embodied in the form of push-buttons and designated by their respective numerals ‘134’, ‘136’.

Referring to the FIG. 2, the second switch 134 is operable to allow illumination of the second visual indication device 132 if an electrical circuit with the NC contacts 137A, 137B of the relay 102 is complete. Moreover, the third switch 136 is operable to energize an electromagnetic coil 124 of the relay 102 and allow illumination of the second visual indication device 132 if the NO contacts 138A, 138B of the relay 102 become closed upon energizing the electromagnetic coil 124 while the NC contacts of the relay become closed.

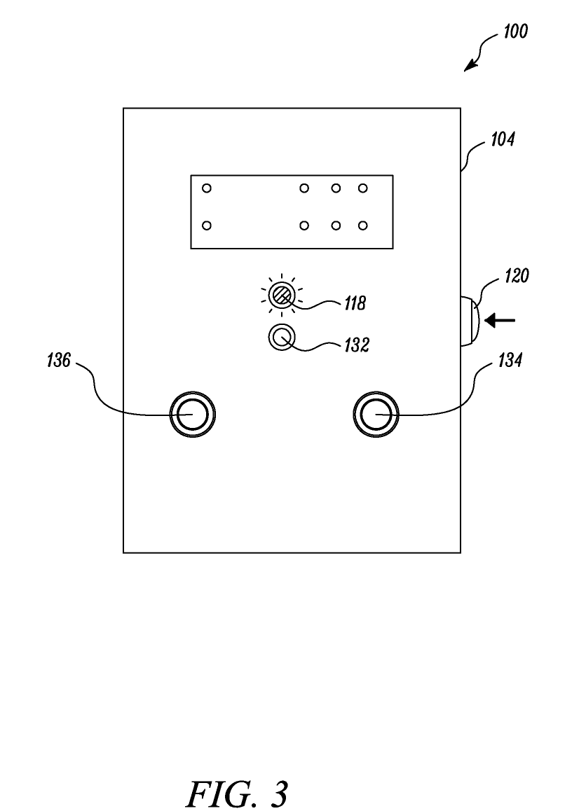

A manner of testing an 8 pin DPDT relay 102 using the apparatus 100 of the present disclosure will be explained in conjunction with FIGS. 3-8. It may be noted that explanation pertaining to the manner of use and operation of the apparatus 100 is provided to merely aid an understanding of the present disclosure. Hence, such explanation should be only taken in the explanatory and illustrative sense without being construed as limiting of the present disclosure.

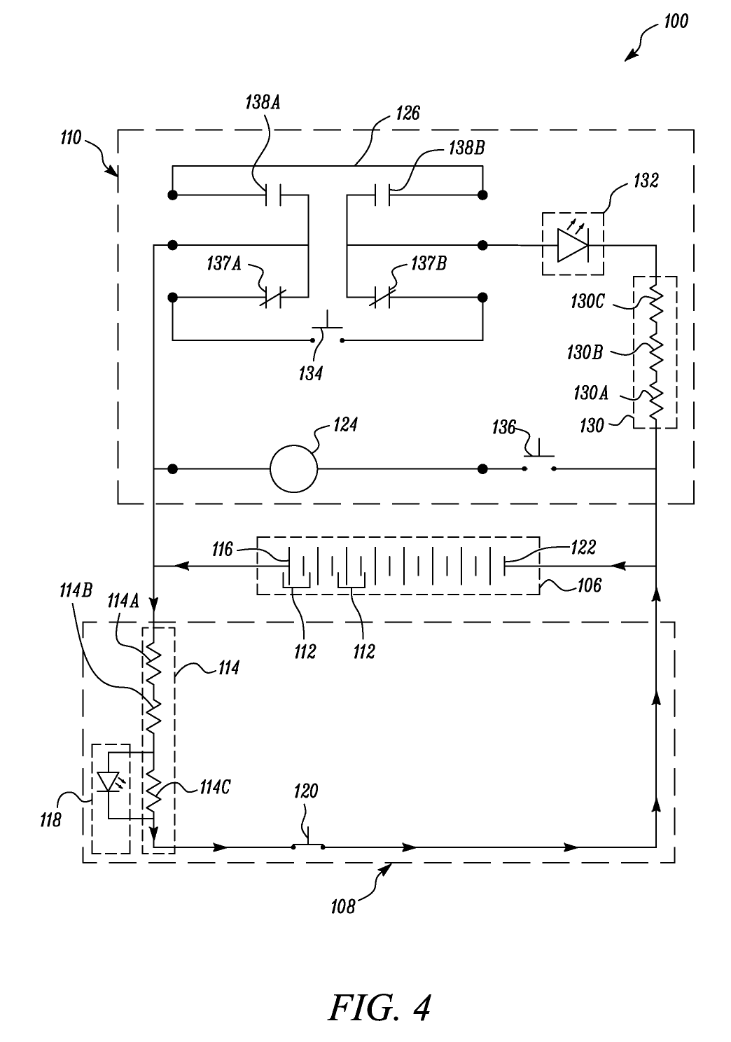

Referring to FIGS. 3 and 4, the apparatus 100 is shown without the relay 102 being connected thereto. As shown, the first switch 120 may be depressed to test if the battery 106 has a minimum output voltage of 18V. If the battery 106 outputs 18V of direct current through the battery test circuit 108, the first visual indication device 118 glows.

If the battery 106 outputs a voltage less than 18V, the first visual indication device 118 may fail to glow. Failure of the first visual indication device 118 to glow upon depression of the first switch 120 may indicate that the battery 106 has insufficient charge to carry out the testing procedures consistent with the present disclosure. However, one may still continue to use the apparatus 100 under such circumstances as well, albeit, with an assumption on the performance of the relay 102 being tested. This is because the electromagnetic coil 124 of the relay 102 can still be energized if the voltage of the battery 106 falls to 16V, although the first visual indication device 118 may fail to glow at a battery voltage below 18V. In such situation where the first visual indication device 118 fails to glow due to a battery voltage below 18V, the battery 106 should be replaced.

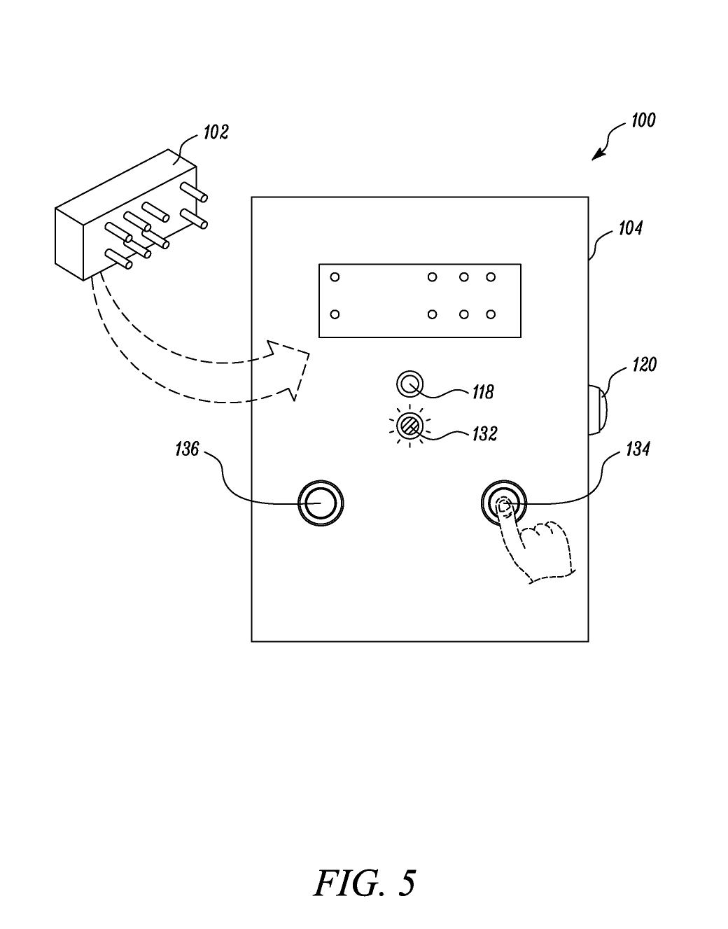

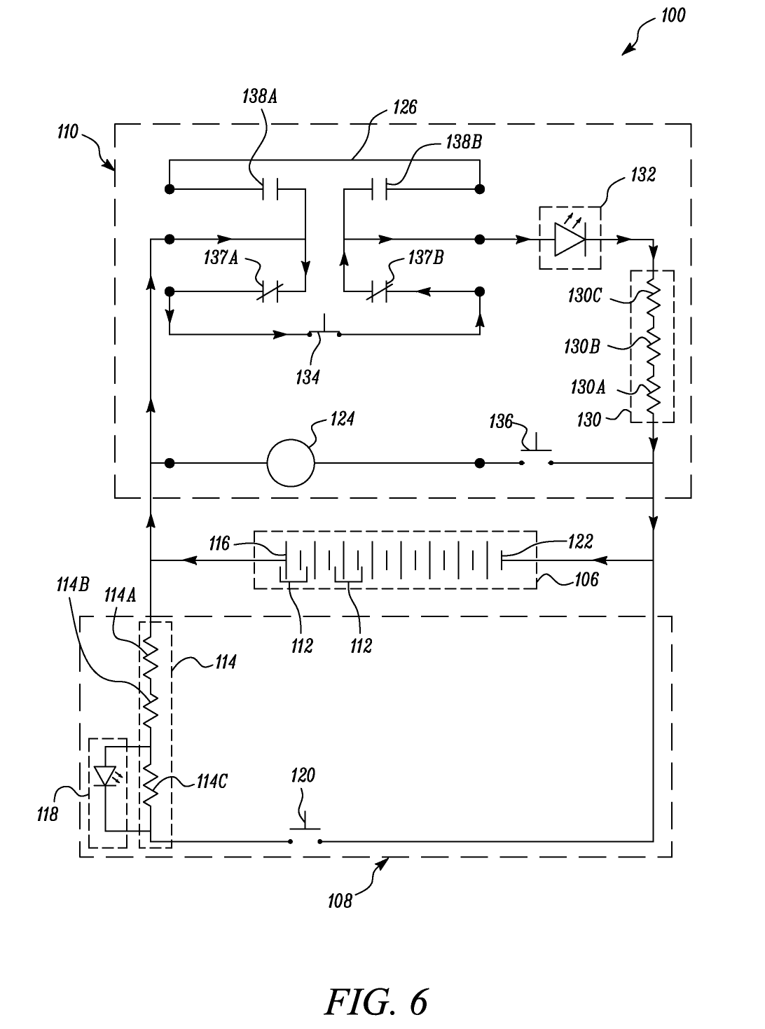

Referring to FIGS. 5 and 6, an 8 pin DPDT relay 102 may be connected to the socket 128 provided on the housing 104. The second switch 134 may now be depressed to determine if the battery 106 makes a closed circuit with the NC contacts 137A, 137B of the relay 102. The second visual indication device 132 may illuminate if the battery 106 makes a closed circuit together with the NC contacts 137A, 137B of the relay 102 thus indicating that the NC contacts 137A, 137B of the relay 102 are performing as intended.

However, if the battery 106 fails to make a closed circuit together with the relay 102 in the NC position, the second visual indication device 132 may fail to illuminate. Failure of the second visual indication device 132 to glow upon depression of the second switch 134 may indicate that the 8 pin DPDT relay 102 is faulty at the time of operation in the NC position.

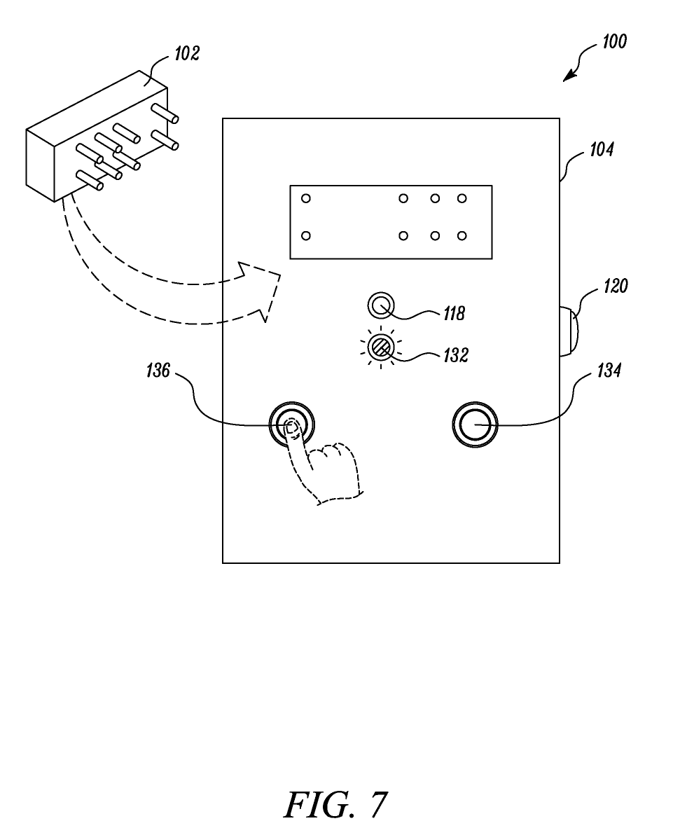

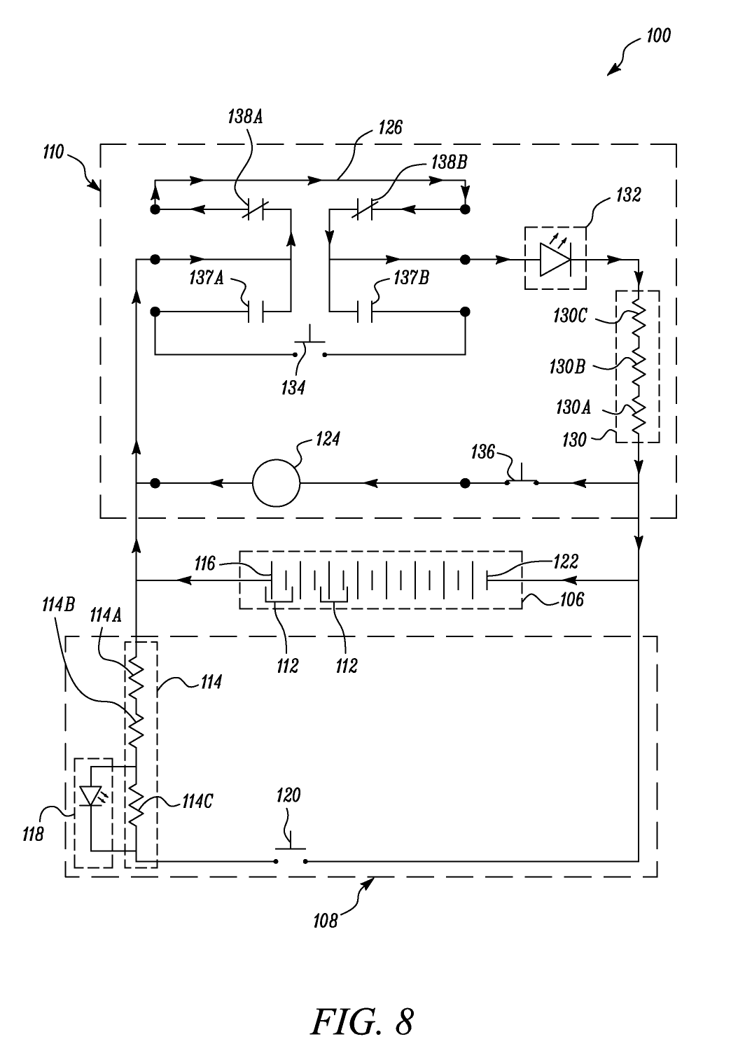

Referring to FIGS. 7 and 8, the second switch 134 is released and the third switch 136 may now be depressed to determine if the battery 106 makes a closed circuit with the Normally Open (NO) contacts 138A, 138B of the relay 102. As such, upon depression of the third switch 136, the electromagnetic coil 124 of the relay 102 is energized. At this point, the second visual indication device 132 may illuminate if the NC contacts 137A, 137B of the relay 102 become open, thus causing the NO contacts 138A, 138B of the relay 102 to become closed upon energizing the electromagnetic coil 124. If the battery 106 completes the circuit together with the NO contacts 138A, 138B of the relay 102 that have closed as the electromagnetic coil 124 of the relay 102 is energized, the second visual indication device 132 may illuminate to indicate that the NO contacts 138A, 138B of the relay 102 are performing as intended.

However, if the battery 106 fails to make a closed circuit together with the NO contacts 138A, 138B of the relay 102, the second visual indication device 132 may fail to illuminate. Failure of the second visual indication device 132 to glow upon depression of the third switch 136 may indicate that the NO contacts 138A, 138B of the relay 102 are faulty at the time of operation.

One of ordinary skill in the art will acknowledge that the testing procedures described in the foregoing disclosure can be beneficially terminated when the second visual indication device 132 fails to illuminate upon depression of either of the second and third switches 134, 136. Moreover, it is hereby contemplated that upon such failure of the second visual indication device 132 to illuminate, the relay 102 may be categorically classified as being faulty and hence, requires replacement.

Various embodiments disclosed herein are to be taken in the illustrative and explanatory sense, and should in no way be construed as limiting of the present disclosure. All directional references (e.g., above, below, upper, lower, top, bottom, vertical, horizontal, inward, outward, radial, upward, downward, left, right, leftward, rightward, clockwise, and counter-clockwise) are only used for identification purposes to aid the reader's understanding of the present disclosure, and may not create limitations, particularly as to the position, orientation, or use of the systems and/or methods disclosed herein. Joinder references (e.g., attached, affixed, coupled, engaged, connected, and the like) are to be construed broadly. Moreover, such joinder references do not necessarily infer that two elements are directly connected to each other.

Additionally, all numerical terms, such as, but not limited to, “first”, “second”, “third”, or any other ordinary and/or numerical terms, should also be taken only as identifiers, to assist the reader's understanding of the various embodiments, variations, components, and/or modifications of the present disclosure, and may not create any limitations, particularly as to the order, or preference, of any embodiment, variation, component and/or modification relative to, or over, another embodiment, variation, component and/or modification.

It is to be understood that individual features shown or described for one embodiment may be combined with individual features shown or described for another embodiment. The above described implementation does not in any way limit the scope of the present disclosure. Therefore, it is to be understood although some features are shown or described to illustrate the use of the present disclosure in the context of functional segments, such features may be omitted from the scope of the present disclosure without departing from the spirit of the present disclosure as defined in the appended claims.

### INDUSTRIAL APPLICABILITY

The apparatus 100 of the present disclosure has applicability in testing of electromechanical relays. Moreover, the apparatus 100 of the present disclosure is configured to allow a self-diagnostic test to be performed on its battery 106 before being used for testing a relay 102. As disclosed herein, the battery test circuit 108 of the apparatus 100 is provided in addition to the relay test circuit 110 so that a technician may operate the first switch 120 and check for the voltage of the battery 106 before using the second and third switches 134, 136 in succession to test a relay 102. This way, the technician can determine if the battery 106 has sufficient voltage prior to testing the relay 102. Sufficient or insufficient voltage may be determined from the illumination of the first visual indication device 118 or failure thereof upon depression of the first switch 120.

The apparatus 100 disclosed herein is portable and can be easily transported from one location to another. Moreover, a size of the apparatus 100, as defined by the housing 104, is configured to fit within the palm of a user. Hence, the apparatus 100 may be handy for use by technicians, service personnel and the like. Further, with implementation of the apparatus 100, electromechanical relays may be quickly connected thereto and easily identified for faulty operation and/or non-operation. Thus, with use of the present apparatus 100, technicians may save time and costs associated with previously known testing apparatuses. Moreover, the present apparatus 100 may allow the technicians to quickly accomplish replacement of faulty electromechanical relays.

While aspects of the present disclosure have been particularly shown and described with reference to the embodiments above, it will be understood by those skilled in the art that various additional embodiments may be contemplated by the modification of the disclosed machines, systems and methods without departing from the spirit and scope of what is disclosed. Such embodiments should be understood to fall within the scope of the present disclosure as determined based upon the claims and any equivalents thereof.

What is claimed is:

1. A portable apparatus for testing an electromechanical relay having Normally Closed (NC) contacts, Normally Open (NO) contacts, and an electromagnetic coil therein, the apparatus comprising:
a housing;
a battery disposed within the housing, the battery having a first terminal and a second terminal disposed in selective communication with a battery test circuit and a relay test circuit, wherein the battery test circuit and the relay test circuit are parallelly arranged to one another, and wherein:
the battery test circuit includes a first switch operable to provide a first type of indication based on a voltage output by the battery; and
the relay test circuit includes:
a second switch operable to provide a second type of indication if an electrical circuit of the relay test circuit is complete with the NC contacts of the relay; and
a third switch operable to energize the electromagnetic coil and provide the second type of indication if the NC contacts of the relay become open and the NO contacts of the relay become closed upon energizing the electromagnetic coil.

2. The apparatus of claim 1, wherein the battery test circuit further comprises:
a first resistance element connected in series and disposed downstream of the first terminal; and
a first visual indication device connected in parallel to the first resistance element.

3. The apparatus of claim 2, wherein the first switch is disposed between the first visual indicator device and the second terminal of the battery.

4. The apparatus of claim 2, wherein the first visual indication device includes a light emitting diode.

5. The apparatus of claim 1, wherein the second switch is connected in series with the Normally Closed (NC) contacts of the relay.

6. The apparatus of claim 1, wherein the relay test circuit further comprises:
a second visual indication device connected in series and disposed downstream of the NC and NO contacts of the relay; and
a second resistance element connected in series with the second visual indication device and disposed between the second visual indication device and the second terminal of the battery.

7. The apparatus of claim 6, wherein the third switch is connected in series with the NO contacts of the relay and the electromagnetic coil of the relay.

8. The apparatus of claim 1, wherein the second visual indication device includes a light emitting diode.

9. The apparatus of claim 1, wherein the housing is configured to fit within the palm of a user.

10. The apparatus of claim 1 further comprising socket configured to allow for the mounting and dismounting of the electromechanical relay that is to be tested.

11. The apparatus of claim 10, wherein the socket is configured to allow connection with a multiple pin relay configuration including but not limited to 8 pin Double Pole Double Throw (DPDT) relay, 5 pin Single Pole Single Throw (SPST) relay, 11 pin DPDT relay, 14 pin DPDT relay.

12. The apparatus of claim 1, wherein the battery includes a plurality of 3 volt button cell Lithium batteries connected in series.

13. A portable apparatus for testing an electromechanical relay having Normally Closed (NC) contacts, Normally Open (NO) contacts, and an electromagnetic coil therein, the apparatus comprising:
a battery having a first terminal and a second terminal;
a battery test circuit communicably connected to the battery, the battery test circuit comprising:
a first resistance element connected in series and disposed downstream of the first terminal;
a first visual indication device connected in parallel to the first resistance element; and
a first switch disposed between the first visual indicator device and the second terminal of the battery, wherein the first switch is operable to allow illumination of the first visual indication device based on a voltage output by the battery; and
a relay test circuit communicably coupled to the battery and disposed parallel to the battery test circuit, the relay test circuit configured to allow connection with the electromagnetic coil, the NC contacts, and the NO contacts of the relay, the relay test circuit comprising:
a second visual indication device connected in series and disposed downstream of the NC and NO contacts of the relay;
a second resistance element connected in series with the second visual indication device and disposed between the second visual indication device and the second terminal of the battery;
a second switch connected in series with the NC contacts of the relay, wherein the second switch is operable to allow illumination of the second visual indication device if an electrical circuit of the relay test circuit is complete with the NC contacts of the relay; and
a third switch connected in series with the NO contacts of the relay and disposed between the second resistance element and the second terminal of the battery, wherein the third switch is operable to energize the electromagnetic coil and provide the second type of indication if the NC contacts of the relay become open and the NO contacts of the relay become closed upon energizing the electromagnetic coil.

14. The apparatus of claim 13, wherein each of the first resistance element and the second resistance element include a series of resistance elements respectively.

15. The apparatus of claim 13, wherein each of the first visual indication device and the second visual indication device include a light emitting diode respectively.

16. The apparatus of claim 13, wherein the first switch is operable to allow illumination of the first visual indication device based on a minimum output voltage of 18 volts or more from the battery.

17. The apparatus of claim 13, wherein the apparatus includes a housing configured to fit within the palm of a user.

18. The apparatus of claim 13 further comprising a socket configured to allow connection with the relay that is to be tested.

19. The apparatus of claim 18, wherein the socket is configured to allow connection with a multiple pin relay configuration, including but not limited to 8 pin Double Pole Double Throw (DPDT) relay, 5 pin Single Pole Single Throw (SPST) relay, 11 pin DPDT relay, 14 pin DPDT relay.

20. The apparatus of claim 13, wherein the battery includes a plurality of 3 volt button cell Lithium batteries connected in series.
